(19) United States
(12) Patent Application Publication
(10) Pub. No.: US 2026/0156876 A1
(43) Pub. Date: Jun. 4, 2026

(54) NEGATIVE CAPACITANCE TRANSISTOR WITH k-Ga2O3/Al2O3 COMPOSITE FERROELECTRIC DIELECTRIC LAYER AND PREPARATION METHOD THEREOF

(71) Applicant: NANJING UNIVERSITY, Nanjing (CN)

(72) Inventors: Jiandong YE, Nanjing (CN); Ke XU, Nanjing (CN); Zhannan GUAN, Nanjing (CN); Changjin WAN, Nanjing (CN); Yurong LUO, Nanjing (CN); Zhanhua LI, Nanjing (CN); Fangfang REN, Nanjing (CN); Shulin GU, Nanjing (CN); Rong ZHANG, Nanjing (CN)

(73) Assignee: NANJING UNIVERSITY, Nanjing (CN)

(21) Appl. No.: 19/405,596

(22) Filed: Dec. 2, 2025

(30) Foreign Application Priority Data
Dec. 3, 2024 (CN) 202411759891.9

(51) Int. Cl. H10D 30/69; H10D 30/01; H10D 30/47; H10D 62/10; H10D 62/824; H10D 64/62; H10D 64/66; H10D 64/68

(52) U.S. Cl. CPC H10D 30/701; H10D 30/475; H10D 62/102; H10D 62/824; H10D 64/62; H10D 64/666; H10D 64/685; H10D 64/689; H10D 30/015; H10D 30/0415

(57) ABSTRACT

The present invention discloses a negative capacitance transistor with a κ-Ga₂O₃/Al₂O₃ composite ferroelectric dielectric layer. The transistor comprises a substrate, a GaN buffer layer, a UID-GaN channel layer, an Al_{0.25}Ga_{0.75}N barrier layer arranged sequentially from bottom to top; a source, a drain, and a gate disposed on the Al_{0.25}Ga_{0.75}N barrier layer; and a κ-Ga₂O₃/Al₂O₃ composite ferroelectric dielectric layer disposed between the gate and the Al_{0.25}Ga_{0.75}N barrier layer. The negative capacitance transistor of the present invention can improve system stability and data retention reliability after power-off while ensuring high-speed data processing capability.

### CROSS-REFERENCE TO RELATED APPLICATIONS

The present application claims priority benefits to Chinese Patent Application No. 202411759891.9 filed on Dec. 3, 2024, which is incorporated herein by reference in its entirety.

### TECHNICAL FIELD

The present invention relates to the technical field of semiconductor devices, specifically to a negative capacitance transistor with a κ-Ga₂O₃/Al₂O₃ composite ferroelectric dielectric layer and a preparation method thereof.

### BACKGROUND

With the continuous evolution of semiconductor technology, the size of transistors continues to shrink, approaching physical limits. However, as device integration density increases, power consumption issues become more prominent. Although methods such as adopting high-k dielectric materials, improving current drive capability, and optimizing device structures can improve performance to a certain extent, these technical means still cannot effectively solve the problem of excessive power consumption. This is because the subthreshold swing (SS) of traditional metal-oxide-semiconductor field-effect transistors (MOSFETs) is limited by Boltzmann statistics, with a minimum value of only 60 mV/dec, which greatly limits the switching speed and energy efficiency of the devices. Therefore, how to break through this bottleneck and develop new low-power devices with lower SS has become a key technical challenge for achieving higher performance and lower power consumption integrated circuits, and is also an important research direction for the future semiconductor industry.

The negative capacitance effect generated during polarization switching in ferroelectric materials can amplify the surface potential of the channel material, thereby effectively reducing the subthreshold swing (SS) of the device and breaking the Boltzmann limit. Thus, they have become an ideal choice for constructing low-power transistors in the post-Moore era. However, in traditional preparation methods, due to the non-epitaxial relationship between the ferroelectric dielectric layer and the channel layer, a large number of interface states exist at the interface. This is because non-epitaxial growth leads to a large number of dangling bonds at the interface. These defects increase leakage current and reduce electron mobility when used in transistor devices, ultimately affecting the overall performance of the device.

To overcome the above problems and achieve the construction of low-power negative capacitance transistors, the present invention adopts epitaxial κ-Ga₂O₃ material on the substrate, significantly reducing the interface state density.

### SUMMARY

The object of the present invention is to overcome the deficiencies of the prior art and to provide a negative capacitance transistor with a κ-Ga₂O₃/Al₂O₃ composite ferroelectric dielectric layer and a preparation method thereof. The present invention forms a κ-Ga₂O₃/Al₂O₃ composite ferroelectric dielectric layer with high interface quality by epitaxially growing a thin film of ferroelectric dielectric material combined with oxygen interface compensation, thereby improving device performance. In the negative capacitance transistor of the present invention, the composite ferroelectric dielectric layer generates a negative capacitance effect during polarization switching, thereby reducing power consumption of the device and enabling the transistor to break through the subthreshold swing limit. Oxygen plasma compensation can effectively improve the interface quality between the ferroelectric layer and the channel material, as well as between the ferroelectric layer and aluminum oxide, reducing the impact of defect capture on ferroelectricity, thereby further enhancing the stability and overall performance of the transistor. The present invention solves the problem in the prior art where the use of ferroelectric dielectric materials to prepare negative capacitance transistors results in significant defect capture due to the ferroelectric hysteresis effect and low interface quality of the ferroelectric material, which affects device performance.

To achieve the above object, the technical solution designed by the present invention is as follows:

The present invention provides a negative capacitance transistor with a κ-Ga₂O₃/Al₂O₃ composite ferroelectric dielectric layer. The negative capacitance transistor comprises a substrate, a GaN buffer layer, a UID-GaN (Unintentionally Doped Gallium Nitride) channel layer, and an Al_{0.25}Ga_{0.75}N barrier layer arranged sequentially from bottom to top; a source region, a drain region, and a gate region defined on a surface of the Al_{0.25}Ga_{0.75}N barrier layer; and a source disposed in the source region, a drain disposed in the drain region, and a gate disposed in the gate region. A two-dimensional electron gas (2DEG) channel is formed at a contact surface between the UID-GaN channel layer and the Al_{0.25}Ga_{0.75}N barrier layer.

The negative capacitance transistor further comprises a κ-Ga₂O₃/Al₂O₃composite ferroelectric dielectric layer disposed between the gate and the Al_{0.25}Ga_{0.75}N barrier layer. The κ-Ga₂O₃/Al₂O₃ composite ferroelectric dielectric layer comprises a κ-Ga₂O₃ ferroelectric layer and an Al₂O₃ insulating layer which are arranged sequentially from bottom to top on the surface of the Al_{0.25}Ga_{0.75}N barrier layer. A material of the κ-Ga₂O₃ ferroelectric layer is κ-Ga₂O₃, and a material of the Al₂O₃ insulating layer is Al₂O₃.

Further, the negative capacitance transistor further comprises a SiNₓ insulating layer, and the SiNₓ insulating layer is disposed on a surface of the negative capacitance transistor except for the gate region.

Still further, an interface between the Al_{0.25}Ga_{0.75}N barrier layer and the κ-Ga₂O₃ ferroelectric layer is a first oxygen compensation interface, an interface between the κ-Ga₂O₃ ferroelectric layer and the Al₂O₃ insulating layer is a second oxygen compensation interface, and the first oxygen compensation interface and the second oxygen compensation interface have a defect density ranging from 1.9×10¹³ cm⁻² to 2.5×10¹³ cm⁻².

Still further, the κ-Ga₂O₃ ferroelectric layer has a thickness of 50-100 nm, and the Al₂O₃ insulating layer has a thickness of 30-50 nm.

The substrate is any one of a silicon substrate, a silicon carbide substrate, and a sapphire substrate, the GaN buffer layer has a thickness of 4-4.5 μm, the UID-GaN channel layer has a thickness of 300-350 nm, the Al_{0.25}Ga_{0.75}N barrier layer has a thickness of 200-250 nm, and the SiNₓ insulating layer has a thickness of 100-150 nm.

Still further, κ-Ga₂O₃ ferroelectric layer has a thickness of 50 nm, and the Al₂O₃ insulating layer has a thickness of 30 nm.

The substrate is the silicon substrate, the GaN buffer layer has a thickness of 4 μm, the UID-GaN channel layer has a thickness of 300 nm, the Al_{0.25}Ga_{0.75}N barrier layer has a thickness of 200 nm, and the SiNₓ insulating layer has a thickness of 100 nm.

Still further, the source and the drain are both Ti/Al/Ni/Au metal stacks, wherein the thicknesses of a Ti layer, an Al layer, a Ni layer, and an Au layer are 20-30 nm, 120-150 nm, 50-60 nm, and 80-100 nm, respectively. The gate is a Ni/Au metal stack, wherein the thicknesses of a Ni layer and an Au layer are 50-60 nm and 80-100 nm, respectively. A distance between the gate and the source is 6-12 μm, and a distance between the gate and the drain is 6-12 μm. The source and drain are formed by stacking the Ti, Al, Ni, and Au layers. The gate is formed by stacking the Ni and Au layers.

The present invention also provides a preparation method for the negative capacitance transistor, comprising the following steps:
(1) cleaning a substrate, and sequentially depositing a GaN buffer layer, a UID-GaN channel layer, and an Al_{0.25}Ga_{0.75}N barrier layer on the surface of the substrate;
(2) using photolithography technology to define a source region and a drain region on the surface of the Al_{0.25}Ga_{0.75}N barrier layer, forming a source and a drain by depositing Ti, Al, Ni, Au metal layers via electron beam evaporation, wherein the source and drain form ohmic contacts with the Al_{0.25}Ga_{0.75}N barrier layer;
(3) depositing a SiNₓ insulating layer on a surface of an epitaxial wafer using plasma-enhanced chemical vapor deposition (PECVD) technology;
(4) using photolithography technology to define a gate region on the surface of the SiNₓ insulating layer, and vertically etching the SiNₓ insulating layer in the gate region until the surface of the Al_{0.25}Ga_{0.75}N barrier layer is exposed;
(5) sequentially growing a κ-Ga₂O₃ ferroelectric layer and an Al₂O₃insulating layer on the surface of the epitaxial wafer;
(6) using a plasma-enhanced etching process to etch the Al₂O₃ insulating layer and the κ-Ga₂O₃ ferroelectric layer in areas other than the gate region until reaching the surface of the SiNₓ insulating layer;
(7) performing photolithography and development on the Al₂O₃ insulating layer in the gate region to form a gate window, depositing Ni and Au metal layers in the gate window to form a gate, thereby obtaining the negative capacitance transistor with the κ-Ga₂O₃/Al₂O₃ composite ferroelectric dielectric layer.

Further, in step (4), after defining the gate region, oxygen plasma treatment is used to remove residual photoresist.

In step (5), after depositing the κ-Ga₂O₃ ferroelectric layer, oxygen plasma treatment is applied to the κ-Ga₂O₃ ferroelectric layer.

The conditions for the oxygen plasma treatment are: radio frequency power of 100-500 W, and processing time of 60 s.

Still further, said preparation method further comprises a sidewall etching step, and the sidewall etching step is set between step (2) and step (3). The sidewall etching step specifically comprising: defining non-active regions along the outer edges of the source and drain, respectively, and etching downward by 200 nm along the non-active regions to form step-notch structures.

In step (3), the SiNₓ insulating layer is deposited using PECVD technology on the surface of the epitaxial wafer and within the step-notch structures.

Still further, the preparation method further comprises a probe window step, The probe window step is set after step (7). The probe window step specifically comprising: performing photolithography and development on the surface of the source and the surface of the drain, respectively, to form probe windows; etching the SiNₓ insulating layer in the probe window on the surface of the source to form a source probe region; and etching the SiNₓ insulating layer in the probe window on the surface of the drain to form a drain probe region.

Principles of the Invention are as follows.
1. The present invention adopts the method of epitaxially growing κ-Ga₂O₃ material on an epitaxial wafer, significantly reducing the interface state density. The reasons for using κ-Ga₂O₃ as the ferroelectric layer are as follows:
(1) κ-Ga₂O₃ has excellent remanent polarization. The theoretical remanent polarization of κ-Ga₂O₃ is 23 μC/cm², and the experimentally measured remanent polarization is 2 μC/cm², which is significantly higher than that of general two-dimensional sliding ferroelectric materials (e.g., Cd₃Cl₆ has a remanent polarization of 0.3-0.4 μC/cm² at room temperature);
(2) κ-Ga₂O₃ also has a relatively small coercive electric field. Its theoretical coercive field is 2.27 MV/cm, while a perovskite material like AlScN has a coercive field of 5 MV/cm. Therefore, the required voltage and power consumption are much lower than those of materials like AlScN. Thus, in comparison, κ-Ga₂O₃, with its excellent coercive field and remanent polarization, shows significant advantages in reducing power consumption of the device and improving switching performance, making it an ideal choice in the field of negative capacitance transistors;
(3) κ-Ga₂O₃ possesses a bandgap of 4.85 eV and a high dielectric constant of 32, exhibiting excellent radiation resistance, good thermal stability, and superior ultraviolet absorption capability. It has become a preferred material in the field of solar-blind ultraviolet detection, widely used in various applications such as space communication, fire monitoring, weather monitoring, and environmental pollution monitoring.
2. The reasons for choosing aluminum oxide to form the composite ferroelectric dielectric layer with gallium oxide are:

Aluminum oxide has a high dielectric constant and low leakage current density, which can effectively reduce charge leakage in the dielectric layer and provide a reliable insulating environment for the device. Furthermore, aluminum oxide has good chemical stability and good chemical compatibility with gallium oxide, allowing the formation of a stable transition layer at the interface and reducing interface defects. Moreover, the thermal expansion coefficient of aluminum oxide is close to that of gallium oxide, helping to maintain interface structural stability under high-temperature process conditions and reducing interface defects caused by thermal stress. Finally, aluminum oxide has a large bandgap (8.8 eV), which can form a deep barrier in the composite ferroelectric dielectric layer, effectively blocking carrier transport and improving device performance.

Beneficial effects of the invention are as follows.
1. The negative capacitance transistor prepared according to the present invention can achieve a subthreshold swing lower than the theoretical limit 60 m V/dec, in contrast to traditional field-effect transistors. In addition, the subthreshold swing is related to the voltage scan rate, specifically, when the voltage scan rate is reduced to 0.003 V/s, the measured minimum subthreshold swing can be 11 mV/dec.
2. In the present invention, oxygen plasma compensates the oxide surface, which can further effectively compensate interface states and more fully realize the regulation of channel electrons by the ferroelectric layer. This process does not cause damage to the channel material surface.
3. The leakage current reduction method of the present invention is applicable to any planar structure transistor. SiNₓ can effectively isolate the current from the gate directly reaching the source through the Al_{0.25}Ga_{0.75}N barrier layer, effectively reducing gate leakage, while aluminum oxide has a good mitigating effect on the leakage tendency caused by the multi-rotation domain crystal structure of κ-Ga₂O₃.
4. The ferroelectric dielectric material κ-Ga₂O₃ in the negative capacitance transistor of the present invention generates a negative capacitance effect during polarization switching, enabling the transistor device to break through the subthreshold swing limit. Epitaxially grown κ-Ga₂O₃ has a lower interface state density compared to other non-epitaxially grown ferroelectric dielectric layers, thereby promoting the regulation of channel electrons by ferroelectric polarization.
5. The κ-Ga₂O₃ prepared in the present invention can be prepared on various substrates, achieving diverse detection forms to meet different detection needs. A device prepared on a sapphire substrate operates in Rayleigh mode, with a resonant frequency of 1.96 GHZ, a phase velocity Up of 3138 m/s, and an electromechanical coupling coefficient k_{eff}² of 0.58%; a device prepared on a silicon carbide substrate operates in Sezawa mode, with a resonant frequency of 3.31 GHz and Up 6640 m/s.
6. The negative capacitance transistor prepared according to the present invention combines multiple modulation modes for electrical signals, possesses dual plasticity (both long-term and short-term plasticity), and due to the wide bandgap characteristics and ferroelectric polarization effect of κ-Ga₂O₃, the transistor combines multiple modulation modes for electrical signals and has good radiation resistance against short-wavelength light. The transistor of the present invention can achieve the combination of volatile and non-volatile memory, thereby improving system stability and data retention reliability after power-off while ensuring high-speed data processing capability. It provides efficient data management support for the application of full reserve pool, reducing migration delay and power consumption, and enhancing its robustness in extreme environments. Therefore, this device can provide efficient data management support for full reserve pool applications and is expected to be widely used in aerospace AI systems.

### BRIEF DESCRIPTION OF THE DRAWINGS

FIG. 1 is a schematic structural diagram of a negative capacitance transistor of the present invention;

FIG. 2 is a schematic structural diagram after depositing a GaN buffer layer, a UID-GaN channel layer, and an Al_{0.25}Ga_{0.75}N barrier layer on a surface of a substrate;

FIG. 3 is a schematic structural diagram after depositing a source and a drain on the structure shown in FIG. 2;

FIG. 4 is a schematic structural diagram after performing sidewall etching on the structure shown in FIG. 3;

FIG. 5 is a schematic structural diagram after depositing a SiNₓ insulating layer on the structure shown in FIG. 4;

FIG. 6 is a schematic structural diagram after defining a gate region on the structure shown in FIG. 5;

FIG. 7 is a schematic structural diagram after epitaxially growing a κ-Ga₂O₃ ferroelectric layer and an Al₂O₃ insulating layer on the structure shown in FIG. 6;

FIG. 8 is a schematic structural diagram after etching the composite ferroelectric dielectric layer in areas other than the gate region of the structure shown in FIG. 7;

FIG. 9 is a schematic structural diagram after depositing a gate on the structure shown in FIG. 8;

FIG. 10 is a schematic structural diagram after forming probe windows on the structure shown in FIG. 9;

FIG. 11 is an optical micrograph of the negative capacitance transistor of the present invention;

FIG. 12 is an X-ray diffraction (XRD) result diagram of the κ-Ga₂O₃ ferroelectric layer;

FIG. 13 is an atomic force microscope (AFM) result diagram of the κ-Ga₂O₃ ferroelectric layer;

FIG. 14 is a piezoresponse force microscopy (PFM) result diagram of the κ-Ga₂O₃ ferroelectric layer;

FIG. 15 is a polarization intensity result diagram of the κ-Ga₂O₃ ferroelectric layer under PUND (Positive-Up-Negative-Down) test;

FIG. 16 is a transfer characteristic curve of the negative capacitance transistor of the present invention before oxygen plasma treatment of the oxide dielectric layer;

FIG. 17 is a transfer characteristic curve of the negative capacitance transistor of the present invention after oxygen plasma treatment of the oxide dielectric layer;

FIG. 18 is a transfer characteristic result diagram of the negative capacitance transistor of the present invention;

FIG. 19 is a subthreshold swing result diagram of the negative capacitance transistor of the present invention;

FIG. 20 is an output characteristic curve of the negative capacitance transistor of the present invention; and

FIG. 21 is a result diagram showing the influence of small and large pulses on the conductance plasticity of the negative capacitance transistor of the present invention.

In the figures: 1. substrate; 2. GaN buffer layer; 3. UID-GaN channel layer; 4. Al_{0.25}Ga_{0.75}N barrier layer; 5. source; 6. drain; 7. gate; 8. κ-Ga₂O₃/Al₂O₃ composite ferroelectric dielectric layer; 9. κ-Ga₂O₃ ferroelectric layer; 10. Al₂O₃ insulating layer; 11. SiN, insulating layer; 12. two-dimensional electron gas channel.

### DETAILED DESCRIPTION OF THE EMBODIMENTS

The present invention will be further described in detail below with reference to specific embodiments to facilitate understanding by those skilled in the art.

### Embodiment 1

This embodiment provides a negative capacitance transistor with a κ-Ga₂O₃/Al₂O₃ composite ferroelectric dielectric layer. As shown in FIG. 1, the negative capacitance transistor comprises a substrate 1, a GaN buffer layer 2, a UID-GaN channel layer 3, and an Al_{0.25}Ga_{0.75}N barrier layer 4 sequentially arranged from bottom to top. The surface of the Al_{0.25}Ga_{0.75}N barrier layer 4 has defined thereon a source region, a drain region, and a gate region. A source 5 is disposed in the source region, a drain 6 is disposed in the drain region, and a gate 7 is disposed in the gate region. A κ-Ga₂O₃/Al₂O₃ composite ferroelectric dielectric layer 8 is disposed between the gate 7 and the Al_{0.25}Ga_{0.75}N barrier layer 4. A SiNₓ insulating layer 11 is disposed on the surface of the epitaxial wafer except for the gate region. The κ-Ga₂O₃/Al₂O₃ composite ferroelectric dielectric layer 8 comprises a κ-Ga₂O₃ ferroelectric layer 9 and an Al₂O₃ insulating layer 10 sequentially arranged from bottom to top on the surface of the Al_{0.25}Ga_{0.75}N barrier layer 4.

A two-dimensional electron gas (2DEG) channel 12 is formed at a contact surface between the UID-GaN channel layer 3 and the Al_{0.25}Ga_{0.75}N barrier layer 4. An interface between the Al_{0.25}Ga_{0.75}N barrier layer 4 and the κ-Ga₂O₃ ferroelectric layer 9 is a first oxygen compensation interface, and an interface between the κ-Ga₂O₃ ferroelectric layer 9 and the Al₂O₃ insulating layer 10 is a second oxygen compensation interface. The first oxygen compensation interface and the second oxygen compensation interface have a defect density ranging from 1.90×10¹³ cm⁻².

In the negative capacitance transistor with the κ-Ga₂O₃/Al₂O₃ composite ferroelectric dielectric layer of this embodiment:
(1) The thickness of the κ-Ga₂O₃ ferroelectric layer 9 is 50-100 nm, and the thickness of the Al₂O₃ insulating layer 10 is 30-50 nm.

Preferably, the thickness of the κ-Ga₂O₃ ferroelectric layer 9 is 50 nm, and the thickness of the Al₂O₃ insulating layer 10 is 30 nm.
(2) The substrate 1 is any one of a silicon substrate, a silicon carbide substrate, and a sapphire substrate.

Preferably, the substrate 1 is the silicon substrate.
(3) The thickness of the GaN buffer layer 2 is 4-4.5 μm, the thickness of the UID-GaN channel layer 3 is 300-350 nm, the thickness of the Al_{0.25}Ga_{0.75}N barrier layer 4 is 200-250 nm, and the thickness of the SiNₓ insulating layer 11 is 100-150 nm.

Preferably, the thickness of the GaN buffer layer 2 is 4 μm, the thickness of the UID-GaN channel layer 3 is 300 nm, the thickness of the Al_{0.25}Ga_{0.75}N barrier layer 4 is 200 nm, and the thickness of the SiNₓ insulating layer 11 is 100 nm.
(4) Both the source 5 and the drain 6 are Ti/Al/Ni/Au metal stacks, wherein the thicknesses of Ti, Al, Ni, and Au layers are 20-30 nm, 120-150 nm, 50-60 nm, and 80-100 nm, respectively. The gate 7 is a Ni/Au metal stack, wherein the thicknesses of a Ni layer and an Au layer are 50-60 nm and 80-100 nm, respectively. The distance between the gate 7 and the source 5 is 6-12 μm, and the distance between the gate 7 and the drain 6 is 6-12 μm.

Preferably, for the source 5 and drain 6, the thicknesses of the Ti layer, Al layer, Ni layer, and Au layer are 20 nm, 120 nm, 50 nm, and 100 nm, respectively. For the gate 7, the thicknesses of the Ni layer and Au layer are 50 nm and 100 nm, respectively. The distance between the gate 7 and the source 5 is 6 μm, and the distance between the gate 7 and the drain 6 is 10 μm.

### Embodiment 2

This embodiment provides a negative capacitance transistor with a κ-Ga₂O₃/Al₂O₃ composite ferroelectric dielectric layer. The structure of the negative capacitance transistor of this embodiment is the same as in Embodiment 1, except that the transistor of this embodiment lacks the SiNₓ insulating layer 11.

The interface between the Al_{0.25}Ga_{0.75}N barrier layer 4 and the κ-Ga₂O₃ ferroelectric layer 9 is a first oxygen compensation interface, the interface between the κ-Ga₂O₃ ferroelectric layer 9 and the Al₂O₃ insulating layer 10 is a second oxygen compensation interface, and the first and second oxygen compensation interfaces both have a defect density of 2.5×10¹³ cm⁻².

### Embodiment 3

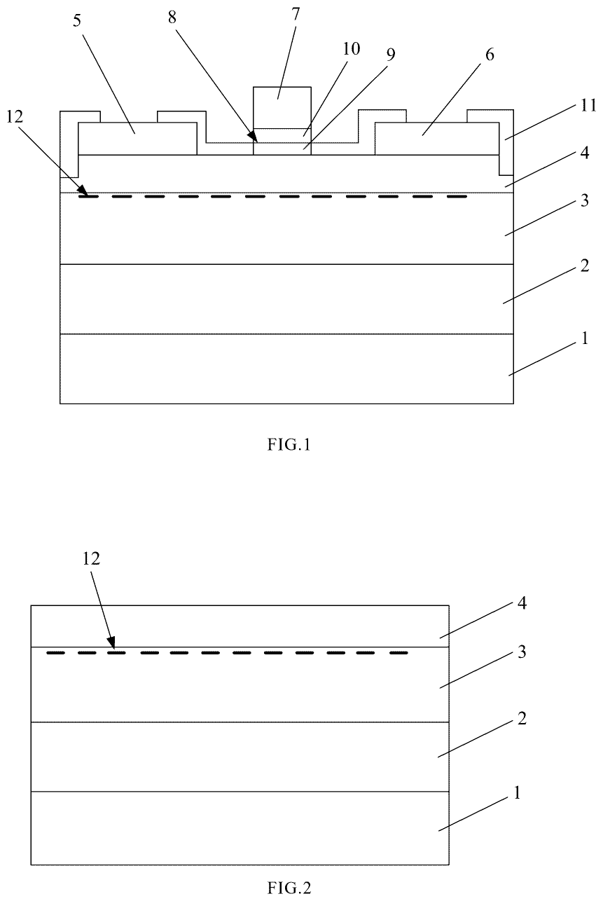

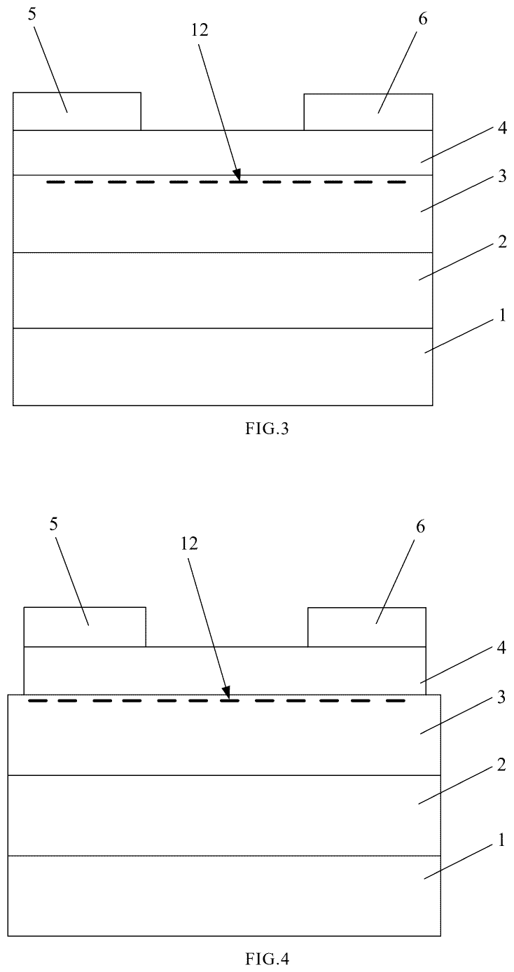

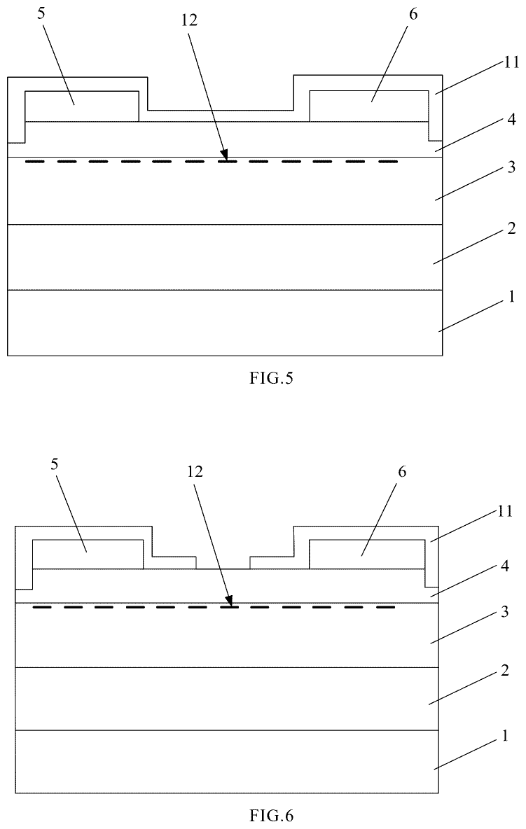

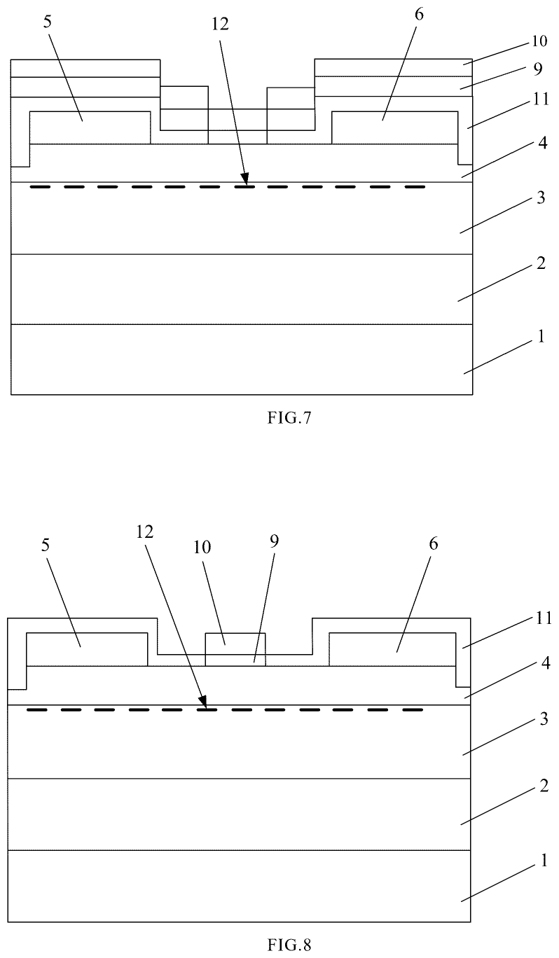

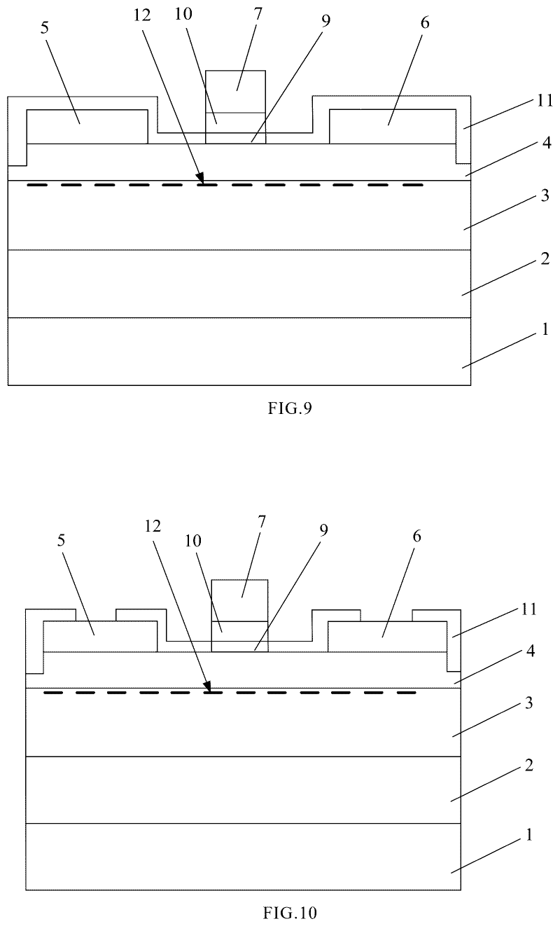

This embodiment provides a preparation method for a negative capacitance transistor with a κ-Ga₂O₃/Al₂O₃ composite ferroelectric dielectric layer. As shown in FIGS. 2-10, the preparation method comprises the following steps:
1. As shown in FIG. 2, a substrate 1 is cleaned, and a GaN buffer layer 2, a UID-GaN channel layer 3, and an Al_{0.25}Ga_{0.75}N barrier layer 4 are sequentially deposited on the surface of the substrate 1. The specific steps are as follows:
(1) A silicon substrate 1 with a (111) crystal plane (a silicon carbide substrate or sapphire substrate can also be used) is selected to reduce lattice mismatch with GaN. The silicon substrate 1 is cleaned using Piranha solution (H₂SO₄+H₂O₂) or hydrogen fluoride (HF) acid.
(2) A GaN buffer layer 2 is prepared on the silicon substrate 1. Specifically, deposition is performed with metal-organic chemical vapor deposition (MOCVD) technology at a temperature of 1050° C., using ammonia (NH₃) as the nitrogen source and triethylgallium (TEGa) as the gallium source, under hydrogen or nitrogen protection with the deposition thickness being 4 μm.
(3) A UID-GaN channel layer 3 is prepared on the GaN buffer layer 2. Specifically, the UID-GaN channel layer 3 is grown using MOCVD technology at a growth temperature of 1050° C.-1100° C., and deposition is performed also using MOCVD technology with the deposition thickness being 300 nm.
(4) An Al_{0.25}Ga_{0.75}N barrier layer 4 is prepared on the UID-GaN channel layer 3. Specifically, the Al_{0.25}Ga_{0.75}N barrier layer 4 is grown using MOCVD technology at a temperature of 1050° C., using triethylaluminum (TEAl) and triethylgallium (TEGa) as metal sources, and NH₃ as the nitrogen source with the deposition thickness being 200 nm.
2. As shown in FIG. 3, photolithography is performed on the Al_{0.25}Ga_{0.75}N barrier layer 4 to define a source region and a drain region. After exposure, oxygen plasma is used to remove residual photoresist. Subsequently, a Ti metal layer, an Al metal layer, an Ni metal layer, and an Au metal layer are sequentially deposited by electron beam evaporation, with thicknesses being 20 nm, 120 nm, 50 nm, and 100 nm, respectively, to form a source 5 and a drain 6. After metal deposition, annealing is performed at 840° C. for 1 min in a nitrogen atmosphere. The source 5 and drain 6 form high-quality ohmic contacts with the Al_{0.25}Ga_{0.75}N barrier layer 4.
3. As shown in FIG. 4, non-active regions and active regions are defined along the outer edges of the source 5 and drain 6, respectively. Using photolithography technology, the active regions are covered by photoresist, and photoresist in the non-active regions falls off after exposure. Then, a reactive ion etch (RIE) process is used to etch downward along the non-active regions into the Al_{0.25}Ga_{0.75}N barrier layer 4. The thickness of the etched material is 200 nm. Due to the protection of the photoresist in the active regions, the active regions remain intact, while the material in the non-active regions is partially etched. Through this method, effective isolation between two devices is achieved, forming step-notch structures, successfully preventing current crosstalk between devices.
4. As shown in FIG. 5, then plasma-enhanced chemical vapor deposition (PECVD) is used to deposit a 100 nm SiNₓ film on the surface of the epitaxial wafer in an atmosphere of silane (SiH₄) and ammonia (NH₃), through a radio frequency plasma reaction, forming a SiN, insulating layer 11.
5. As shown in FIG. 6, photolithography technology is used to define a gate region on the surface of the SiNₓ insulating layer 11, and oxygen plasma is used to remove residual photoresist (oxygen plasma treatment conditions: RF power range of 100-500 W, plasma treatment duration fixed at 60 s). Subsequently, a plasma-enhanced etching (RIE) process is used in a mixed atmosphere of fluorine-based gas (e.g., SF₆ or CHF₃) and oxygen to perform anisotropic etching on the SiNₓ insulating layer 11 within the gate region until the surface of the Al_{0.25}Ga_{0.75}N barrier layer 4 is exposed. Then cleaning is performed with acetone to remove remaining photoresist.
6. As shown in FIG. 7, then Mist-CVD (Mist Chemical Vapor Deposition) (PLD (Pulsed Laser Deposition) or MOCVD can also be used) is used to epitaxially grow a 50 nm κ-Ga₂O₃ film on the surface of the epitaxial wafer, with the temperature set at 700° C. A precursor solution is prepared by dissolving gallium chloride (GaCl₃) in deionized water or an alcohol solution (e.g., methanol, ethanol), and epitaxial growth is carried out in an oxygen atmosphere, forming a κ-Ga₂O₃ ferroelectric layer 9. Oxygen plasma treatment is applied to the κ-Ga₂O₃ ferroelectric layer 9 (oxygen plasma treatment conditions: RF power range of 100-500 W, and plasma treatment duration fixed at 60 s). Subsequently, atomic layer deposition (ALD) is used to alternately introduce trimethylaluminum (TMA) and water vapor to react on the surface of the κ-Ga₂O₃ ferroelectric layer 9, depositing a 30 nm Al₂O₃ film layer by layer, forming an Al₂O₃ insulating layer 10.
7. As shown in FIG. 8, photolithography technology is used on areas outside the gate region for exposing and then developing to expose the κ-Ga₂O₃ ferroelectric layer 9, Al₂O₃ insulating layer 10, and SiNₓ insulating layer 11. Then, oxygen plasma is used to remove residual photoresist. Subsequently, an RIE process is used to etch away the Al₂O₃ insulating layer 10 and the κ-Ga₂O₃ ferroelectric layer 9, retaining the SiNₓ insulating layer 11.
8. As shown in FIG. 9, photolithography and development are performed on the Al₂O₃ insulating layer 10 to form a gate window. Then, oxygen plasma is used to remove residual photoresist. Subsequently, a Ni electrode and an Au electrode are deposited in the gate window by electron beam evaporation to form a gate 7. The thicknesses of the Ni layer and Au layer are 50 nm and 100 nm, respectively. After preparation, an acetone solution is used for metal lift-off to remove excess metal, completing the fabrication of the gate 7 (the distance between the gate 7 and the source 5 is 6 μm, and the distance between the gate 7 and the drain 6 is 10 μm).
9. As shown in FIG. 10, photolithography and development are performed on the surface of the source 5 and the surface of the drain 6, respectively, to form probe windows. Then, oxygen plasma is used to remove residual photoresist. Subsequently, RIE etching is used to etch the SiNₓ insulating layer 11 in the probe window on the source 5 surface to form a probe region of the source 5, and the SiNₓ insulating layer 11 in the probe window on the drain 6 surface is etched to form a probe region of the drain 6, thereby obtaining the negative capacitance transistor with the κ-Ga₂O₃/Al₂O₃composite ferroelectric dielectric layer. The minimum subthreshold swing of this transistor is 11 mV/dec.

### Embodiment 4

This embodiment provides a preparation method for a negative capacitance transistor with a κ-Ga₂O₃/Al₂O₃ composite ferroelectric dielectric layer. The preparation steps are the same as in Embodiment 3, except for the following differences:
(1) The thickness of the κ-Ga₂O₃ ferroelectric layer 9 is 100 nm, and the thickness of the Al₂O₃ insulating layer 10 is 50 nm;
(2) The thickness of the GaN buffer layer 2 is 4.5 μm, the thickness of the UID-GaN channel layer 3 is 350 nm, the thickness of the Al_{0.25}Ga_{0.75}N barrier layer 4 is 250 nm, and the thickness of the SiNₓ insulating layer 11 is 150 nm;
(3) For the source 5 and drain 6, the thicknesses of the Ti layer, Al layer, Ni layer, and Au layer are 30 nm, 150 nm, 60 nm, and 80 nm, respectively; for the gate 7, the thicknesses of the Ni layer and Au layer are 60 nm and 80 nm, respectively; the distance between the gate 7 and the source 5 is 12 μm, and the distance between the gate 7 and the drain 6 is 6 μm.

### Embodiment 5

This embodiment provides a preparation method for a negative capacitance transistor with a κ-Ga₂O₃/Al₂O₃ composite ferroelectric dielectric layer. The preparation steps are the same as in Embodiment 3, except for the following differences:
(1) The thickness of the κ-Ga₂O₃ ferroelectric layer 9 is 80 nm, and the thickness of the Al₂O₃ insulating layer 10 is 40 nm;
(2) The thickness of the GaN buffer layer 2 is 4.2 μm, the thickness of the UID-GaN channel layer 3 is 320 nm, the thickness of the Al_{0.25}Ga_{0.75}N barrier layer 4 is 230 nm, and the thickness of the SiNₓ insulating layer 11 is 120 nm;
(3) For the source 5 and drain 6, the thicknesses of the Ti layer, Al layer, Ni layer, and Au layer are 25 nm, 130 nm, 55 nm, and 90 nm, respectively; for the gate 7, the thicknesses of the Ni layer and Au layer are 55 nm and 90 nm, respectively; the distance between the gate 7 and the source 5 is 10 μm, and the distance between the gate 7 and the drain 6 is 12 μm.

### Embodiment 6

Performance Testing of the Negative Capacitance Transistor with κ-Ga₂O₃/Al₂O₃Composite Ferroelectric Dielectric Layer

FIG. 11 is an optical micrograph of the negative capacitance transistor of Embodiment 1. The transistor has a top-gate structure.

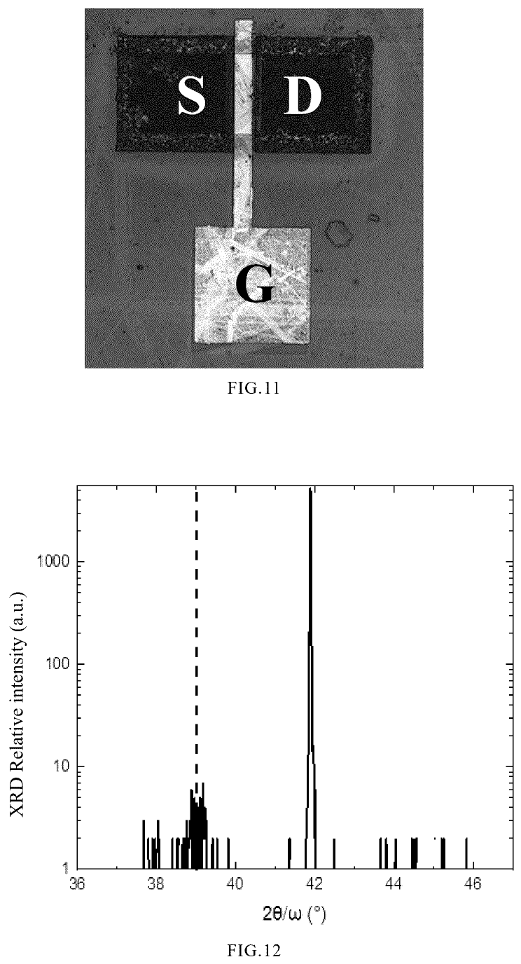

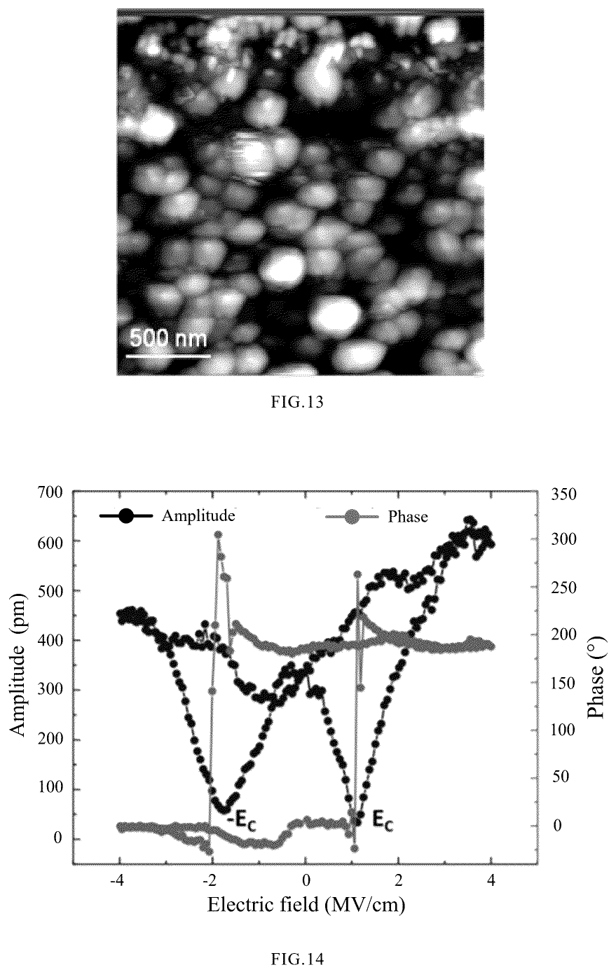

FIG. 12 is an X-ray diffraction (XRD) result diagram of the 50 nm κ-Ga₂O₃ ferroelectric layer prepared by Embodiment 1, showing that the prepared κ-Ga₂O₃ is a single phase. FIG. 13 is an atomic force microscope (AFM) result diagram of the 50 nm κ-Ga₂O₃ ferroelectric layer prepared by Embodiment 1. The κ-Ga₂O₃ film has a smooth and uniform surface with a roughness of 9.1 nm, and the growth mode is island growth.

FIG. 14 is a piezoresponse force microscopy (PFM) image of the 50 nm κ-Ga₂O₃ ferroelectric layer. The results show that the film exhibits clear phase inversion and a certain amplitude response.

FIG. 15 is a polarization intensity result diagram of the 50 nm κ-Ga₂O₃ ferroelectric layer measured by PUND test. The results show that the material has a remanent polarization of 2 μC/cm².

### Embodiment 7

Test of the Effect of Oxygen Plasma Treatment on the Oxide Dielectric Layer (Ga₂O₃ Ferroelectric Layer) of the Negative Capacitance Transistor of the Present Invention

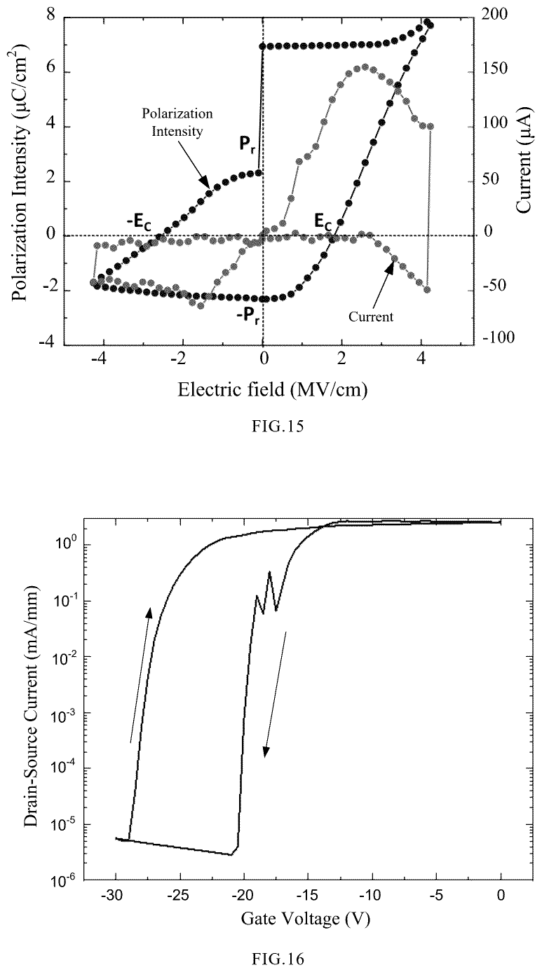

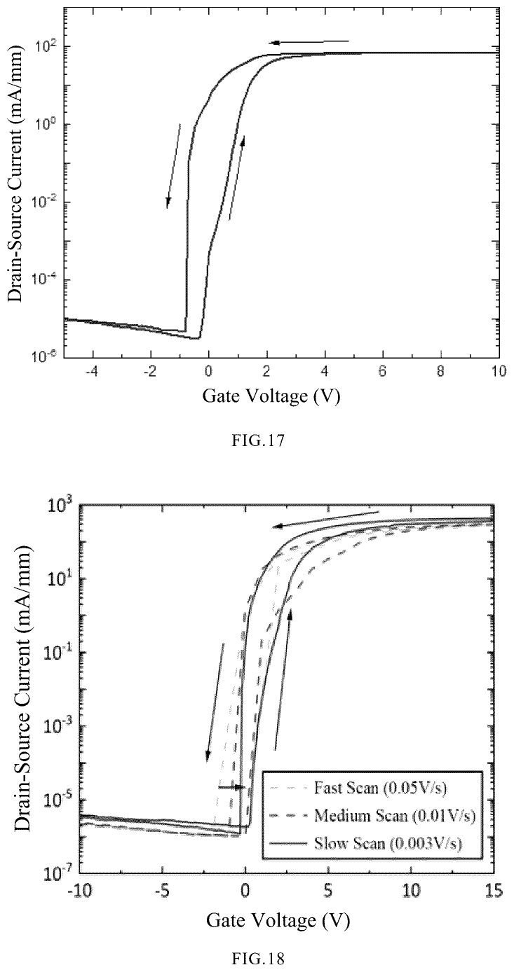

FIG. 16 is a transfer characteristic curve of the negative capacitance transistor of the present invention before oxygen plasma treatment of the oxide dielectric layer (Ga₂O₃ ferroelectric layer). FIG. 17 is a transfer characteristic curve of the negative capacitance transistor of the present invention after oxygen plasma treatment of the oxide dielectric layer (Ga₂O₃ ferroelectric layer). The results show that before treatment, the hysteresis of the transfer curve is clockwise, representing the dominant role of the defect capture mechanism. After treatment, the hysteresis of the transfer characteristic curve is counterclockwise, representing the dominant role of the ferroelectric polarization switching mechanism. After oxygen plasma treatment of the oxide dielectric layer of the negative capacitance transistor of the present invention, the concentration of acceptor interface states decreases, and the barrier near the semiconductor surface is further reduced. Therefore, the defect capture mechanism becomes a secondary factor, and the formation of the ferroelectric polarization-induced channel becomes the main factor, making the performance of the negative capacitance transistor more excellent.

### Embodiment 8

Subthreshold Swing Detection of the Negative Capacitance Transistor with κ-Ga₂O₃/Al₂O₃ Composite Ferroelectric Dielectric Layer

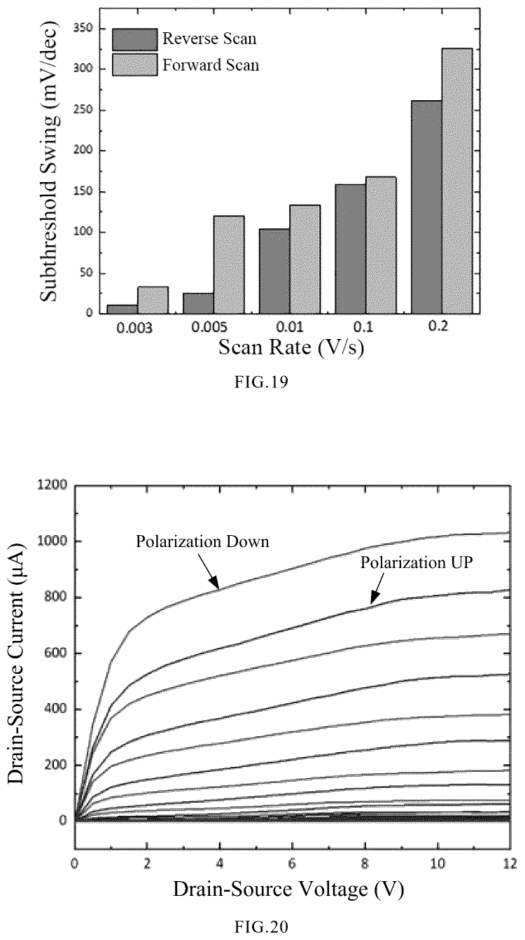

FIG. 18 is a transfer characteristic result diagram of the negative capacitance transistor of Embodiment 1. FIG. 19 is a subthreshold swing result diagram of the negative capacitance transistor of Embodiment 1. The results show that the transfer characteristic curve of the transistor exhibits counterclockwise hysteresis, and the subthreshold swing breaks the Boltzmann limit, dropping below 60 mV/dec. Meanwhile, the subthreshold swing is also affected by a voltage scan rate. Specifically, when the scan rate is 0.003 V/s, the measured minimum subthreshold swing is 11 mV/dec.

FIG. 20 is an output characteristic curve of the negative capacitance transistor of Embodiment 1. The output characteristic curve shows that the ferroelectric polarization switching of κ-Ga₂O₃ has a significant modulation effect on the channel conductance.

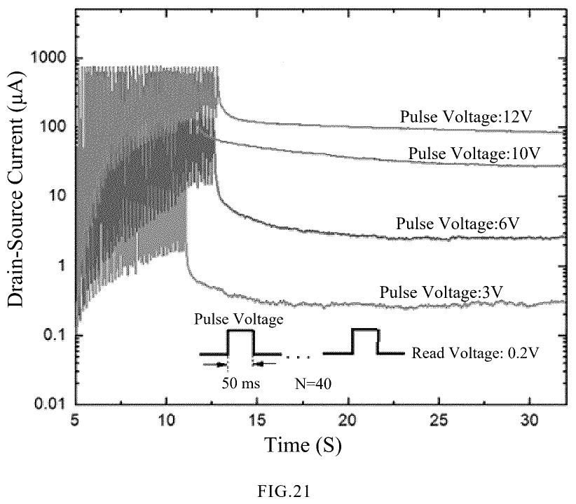

FIG. 21 shows the influence of small and large pulses on the conductance plasticity of the negative capacitance transistor of Embodiment 1. When the pulse voltage is close to the coercive voltage of κ-Ga₂O₃, the transistor can maintain conductance after the pulse is removed, exhibiting non-volatile memory characteristics. When the pulse voltage is much lower than the coercive voltage, the transistor “forgets” the conductance after the pulse is removed, exhibiting volatile memory characteristics.

Other parts not described in detail are prior art. Although the above embodiments describe the present invention in detail, they are only part of the embodiments of the present invention, not all embodiments. Other embodiments can be obtained by those skilled in the art without creative effort based on these embodiments, and all these embodiments fall within the protection scope of the present invention.

What is claimed is:

1. A negative capacitance transistor with a κ-Ga₂O₃/Al₂O₃ composite ferroelectric dielectric layer, the negative capacitance transistor comprising: a substrate, a GaN buffer layer, a UID-GaN channel layer, and an Al_{0.25}Ga_{0.75}N barrier layer arranged sequentially from bottom to top; a source region, a drain region, and a gate region defined on a surface of the Al_{0.25}Ga_{0.75}N barrier layer; a source disposed in the source region, a drain disposed in the drain region, and a gate disposed in the gate region; a two-dimensional electron gas (2DEG) channel is formed at an interface between the UID-GaN channel layer and the Al_{0.25}Ga_{0.75}N barrier layer;
wherein the negative capacitance transistor further comprises a κ-Ga₂O₃/Al₂O₃composite ferroelectric dielectric layer disposed between the gate and the Al_{0.25}Ga_{0.75}N barrier layer, the κ-Ga₂O₃/Al₂O₃ composite ferroelectric dielectric layer comprises a κ-Ga₂O₃ ferroelectric layer and an Al₂O₃ insulating layer which are arranged sequentially from bottom to top on the surface of the Al_{0.25}Ga_{0.75}N barrier layer, a material of the κ-Ga₂O₃ ferroelectric layer is κ-Ga₂O₃, and a material of the Al₂O₃ insulating layer is Al₂O₃.

2. The negative capacitance transistor according to claim 1, wherein the negative capacitance transistor further comprises a SiNₓ insulating layer, and the SiNₓ insulating layer is disposed on a surface of the negative capacitance transistor except for the gate region.

3. The negative capacitance transistor according to claim 1, wherein an interface between the Al_{0.25}Ga_{0.75}N barrier layer and the κ-Ga₂O₃ ferroelectric layer is a first oxygen compensation interface, an interface between the κ-Ga₂O₃ ferroelectric layer and the Al₂O₃ insulating layer is a second oxygen compensation interface, and the first oxygen compensation interface and the second oxygen compensation interface have a defect density ranging from 1.9×10¹³ cm⁻² to 2.5×10¹³ cm⁻².

4. The negative capacitance transistor according to claim 2, wherein the κ-Ga₂O₃ ferroelectric layer has a thickness of 50-100 nm, and the Al₂O₃ insulating layer has a thickness of 30-50 nm;
the substrate is any one of a silicon substrate, a silicon carbide substrate, and a sapphire substrate, the GaN buffer layer has a thickness of 4-4.5 μm, the UID-GaN channel layer has a thickness of 300-350 nm, the Al_{0.25}Ga_{0.75}N barrier layer has a thickness of 200-250 nm, and the SiNₓ insulating layer has a thickness of 100-150 nm.

5. The negative capacitance transistor according to claim 4, wherein the thickness of the κ-Ga₂O₃ ferroelectric layer is 50 nm, and the thickness of the Al₂O₃ insulating layer is 30 nm;
the substrate is the silicon substrate, the thickness of the GaN buffer layer is 4 μm, the thickness of the UID-GaN channel layer is 300 nm, the thickness of the Al_{0.25}Ga_{0.75}N barrier layer is 200 nm, and the thickness of the SiNₓ insulating layer is 100 nm.

6. The negative capacitance transistor according to claim 1, wherein both the source and the drain are Ti/Al/Ni/Au metal stacks, a Ti layer, an Al layer, a Ni layer, and an Au layer have thicknesses of 20-30 nm, 120-150 nm, 50-60 nm, and 80-100 nm, respectively; the gate is a Ni/Au metal stack, a Ni layer and an Au layer have thicknesses of 50-60 nm and 80-100 nm, respectively; a distance between the gate and the source is 6-12 μm, and a distance between the gate and the drain is 6-12 μm.
